(19) United States
(12) Patent Application Publication
(10) Pub. No.: US 2018/0369861 A1
(43) Pub. Date: Dec. 27, 2018

(54) FILM FORMING METHOD

(71) Applicant: FLOSFIA INC., Kyoto (JP)

(72) Inventors: Shigetaka KATORI, Okayama (JP); Kazuaki HIROKI, Okayama (JP); Masaya ODA, Kyoto (JP); Toshimi HITORA, Kyoto (JP)

(21) Appl. No.: 16/061,172

(22) PCT Filed: Dec. 21, 2016
(86) PCT No.: PCT/JP2016/088256

§ 371 Date: Jun. 11, 2018

(30) Foreign Application Priority Data
Dec. 24, 2015 (JP) 2015-252319
Mar. 18, 2016 (JP) 2016-056303

(51) Int. Cl. B05D 3/10; C23C 16/448; H01L 51/44; B05D 3/00

(52) U.S. Cl. CPC B05D 3/10; B05D 3/002; H01L 51/44; C23C 16/448

(57) ABSTRACT

According to an object to offer a film in quality with an industrial advantage, a method of forming a film is suggested. An embodiment of a method of the present invention includes turning a raw-material solution containing an aprotic solvent (that may be lactones or lactams) into a mist or droplets (step of atomization), carrying the mist or droplets into a film-formation chamber onto a base that is arranged in the film-formation chamber (step of carrying the mist), and causing a reaction of the mist or droplets preferably at a temperature that is 250° C. or less to form a film on the base (step of forming a film).

### TECHNICAL FIELD

The present invention relates to a mist CVD method to form a thin film using mist particles obtained through atomization of a solution.

### BACKGROUND ART

Generally, metal oxide thin films used for solar cells, liquid crystal display devices or other devices are manufactured by methods such as a sputtering method, a vapor deposition method, and a CVD (Chemical Vapor Deposition) method using an organometal compound. A sputtering method and an evaporation method that are vacuum processes require vacuum devices. An organometal chemical vapor deposition method requires a vacuum device, and organometal compounds with explosive properties and toxicity may be used as raw materials in the organometal chemical vapor deposition method, and thus, have a difficulty in handling. Accordingly, such an organometal chemical vapor deposition requires accompanying equipment including an exhaust gas treatment device and a design for a high degree of safety in an overall system of film-formation. Any of these requirements tends to be a problem to block cost reduction. Also, some substrates increase in size recently, and that becomes a problem in particular.

Under such circumstances, a mist CVD method that is able to form films from raw materials without a vacuum process in a safer way with less cost is considered. Non-Patent Document 1 describes forming a ZnO transparent electrically-conductive film using a mist CVD method. In addition, studies and researches on ZnO have been proceeding, and in recent years, for example, Patent Document 1 describes that the regrowth step of forming a ZnO-based single crystalline thin film is performed by the mist CVD method.

Recently, it has been studied to form a thin film of a corundum-structured transition metal oxide such as α-Fe₂O₃, α-Cr₂O₃, α-V₂O₃, α-Ti₂O₃, and α-Rh₂O₃ by using a mist CVD method (Non-Patent Document 2). In particular, α-Ga₂O₃ has a large band gap and is expected to be applied to a semiconductor device. By use of the mist CVD method, gallium oxide with such a metastable phase corundum structure is able to be formed. Also, it is described in the Non-Patent Document 2 that band gap control is possible by mixing indium or aluminum respectively with gallium oxide or forming a mixed crystal in combination thereof, suggesting a highly attractive material group as an InAlGaO-based semiconductor. Here, the InAlGO-based semiconductor refers to InxAlyGazO₃ (0≤X≤2, 0≤Y≤2, 0≤Z≤2, X+Y+Z=1.5 to 2.5), which is able to be viewed as a same material group containing gallium oxide.

Meanwhile, there is a material which has been recently attracting attention in addition to gallium oxide, and that is a perovskite complex oxide having a perovskite structure, for example. Perovskite composite oxides exhibit various physical properties, and thus, have been used and studied in a wide range of fields. Such perovskite composite oxide s indicate to have physical properties including anionic conduction such as oxide ion conduction, cation conduction such as lithium ion conduction, proton conduction, electron conduction, ferroelectricity, ferromagnetism and high temperature superconductivity.

Regarding methods for producing a perovskite composite oxide, as described in Patent Document 2, a physical vapor deposition method, a chemical vapor deposition method, a sol-gel method, an MOD method or the like are stated as techniques for forming a lead-based ferroelectric film, and a mist CVD method is also stated as an example. However, as described in Patent Document 2, a film formed on a substrate by one of those methods has to be thermally treated, and especially to obtain a film having a tetragonal perovskite structure, it is necessary to anneal the film at temperatures from 600° C. to 800° C. for crystallization. Also, there is no example to form a tetragonal perovskite film by a mist CVD method, and the mist CVD method described in Patent Document 2 differs from the mist CVD method that has been recently studied for manufacture an α-Ga₂O₃ based semiconductor, suggesting that after atomized raw-material solution is applied onto a substrate, and then, thermally treated.

In addition, Patent Document 3 discloses a spin coating method, a chemical vapor deposition (CVD) method, a sputtering method, and the like as a method for producing a perovskite composite oxide, and further discloses a mist CVD method in which an atomized ferroelectric material solution is applied onto a substrate, then thermally treated. However, as described in Patent Document 3, the perovskite composite oxide obtained by deposition does not indicate practical characteristics as it is, and thus, requires to be annealed for crystallization. When the perovskite composite oxide is annealed, there tends to be a problem of deterioration in properties of the perovskite composite oxide due to a reaction occurring at an interface, a diffusion or separation of constituent atoms of a film, and a release of oxygen from the constituent atoms of the film. Accordingly, Patent Document 3 suggests that a film is irradiated by a continuous wave laser beam, instead of annealing the film. However, such a laser beam irradiation tends to have problems. Since heat of the laser beam irradiated to the oxide layer is likely to escape through a base layer arranged under the oxide layer, it is difficult to selectively and sufficiently enhance the temperature of the oxide layer, the oxide is not sufficiently crystallized and/or the base layer tends to be oxidized. Also, it is noted that there is no actual example reported to form a perovskite film by a mist CVD method. The mist CVD method described in Patent Document 3 differs from the mist CVD method that has been recently studied for manufacturing an α-Ga₂O₃-based semiconductor, suggesting that atomized raw-material solution is applied onto a substrate, then, thermally treated. Also, there tends to be a problem such as a break of crystal structure, increase in dislocation density, generation of pits, and loss of surface smoothness, and also impurities tend to enter a film due to anneal treatment, and thus, a method capable of forming a perovskite film without annealing treatment has been desired.

As mentioned above, the mist CVD method has been attracting particular attention as a method capable of producing new functional materials in recent years, but it is not yet satisfactory for its implementation. Accordingly, a method capable of producing materials that are highly functional materials and/or new materials more easily has been desired.

### CITATION LIST

### Patent Literature

PTL 1: JP 2013-251411
PTL 2: JP H10-172348
PTL 3: WO 2008/004571

### Non-Patent Literature

NPL 1: Kawaharamura, Toshiyuki, “Mist CVD method and the method applied to form a zinc oxide thin film”, Dissertation, Kyoto Univ., March 2008.
NPL 2: Kaneko, Kentaro, “Fabrication and physical properties of corundum structured alloys based on gallium oxide”, Dissertation, Kyoto Univ., March 2013.

### SUMMARY OF THE INVENTION

### Technical Problem

The present invention has an object to obtain a film in a required quality level or an object to enhance quality of a film. Also, the present invention has an object to offer a method for forming a film industrially advantageously.

### Solution to Problem

As a result of keen examination to achieve an object mentioned above, the present inventors found out a method to form a perovskite film having a perovskite structure in a required quality level without annealing treatment. The method includes forming a mist or droplets atomized from a raw-material solution, carrying the mist or droplets onto a base by a carrier gas, and causing a reaction of the mist or droplets to form a film on the base. Also, the present inventors found out that such a method may be useful to obtain a film in a required quality level or to enhance quality of a film. Furthermore, the present inventors found out that it is possible to solve a problem and to form a film industrially advantageously. The present inventors made further examination for the present invention.

The present invention is related to the followings.
[1] A method of forming a film includes turning a raw-material solution containing an aprotic solvent by atomization into a mist or droplets, carrying the mist or droplets by a carrier gas onto a base, and forming a film on the base by a reaction of the mist or droplets.
[2] According to the method of forming the film of [1], the aprotic solvent is represented by Chemical Formula 1,

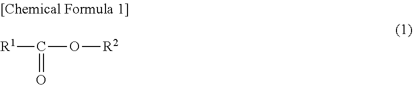

in the Chemical Formula (1), wherein

R¹ and R² are the same or different and each represents a hydrogen atom, a halogen atom, an optionally substituted hydrocarbon group or an optionally substituted heterocyclic group, and

R¹ and R² may be taken together to form a ring.
[3] According to the method of forming the film of [1], the aprotic solvent is represented by Chemical Formula 2,

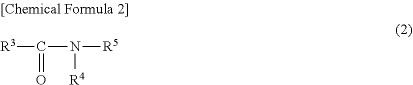

in the Chemical Formula (2), wherein
R³, R⁴, and R⁵ are the same or different and each represents a hydrogen atom, a halogen atom, an optionally substituted hydrocarbon group, or an optionally substituted heterocyclic group, and two arbitrary groups selected from among R³, R⁴, and R⁵ may bond each other to form a ring.
[4] According to any of [1] to [3] of the method of forming the film, the raw-material solution contains an organometal halide compound.
[5] According to any of [1] to [4] of the method of forming the film, the raw-material solution contains an ammonium compound.
[6] According to any of [1] to [5] of the method of forming the film, the reaction of the mist or droplets is a thermal reaction of the mist or droplets conducted at 250° C. or less.
[7] According to any of the method [1] to [6] of forming the film, the base is a glass substrate.
[8] According to any of the method [1] to [7] of forming the base, the base includes a tin-doped indium oxide layer or a fluorine-doped indium oxide layer.
[9] According to any of the method [1] to [8] of forming the base, the base includes a titania layer.
[10] A film obtained by any of the method [1] to [9] of forming the film.
[11] The film of [10] includes a Perovskite structure.
[12] A photoelectric-conversion element includes the film of [11].
[13] The method of [1] or [2], wherein the raw-material solution contains an amine derivative.
[14] The method of [1] or [2], wherein the raw-material solution contains a metal complex.
[15] A method of manufacturing an organic light-emitting element comprising: forming a hole transport layer and/or a light-emitting layer that is directly or via another layer on a base by forming a mist or droplets by atomization of a raw-material solution comprising an aprotic solvent, carrying the mist or droplets by a carrier gas onto a base, and forming the hole transport layer and/or the light-emitting layer on the base by causing a reaction of the mist or droplets on the base.
[16] The method of claim 15, wherein the raw-material solution comprises an amine derivative.
[17] The method of claim 15, wherein the raw-material solution comprises a metal complex.
[18] An organic light-emitting element obtained by the method according to any of claims 15 to 17.

### Advantageous Effects of Invention

According to an embodiment of the present invention, a film in quality with an industrial advantage is obtainable.

### BRIEF DESCRIPTION OF THE DRAWINGS

FIG. 1 shows a schematic diagram of a film-formation apparatus (that is mist CVD) used in an embodiment of the present invention.

FIG. 2 shows a result of XRD of an embodiment.

FIG. 3 shows a result of SEM observation of an embodiment. The image (a) shows a SEM image of 250 times magnification, the image (b) shows a SEM image of 1000 times magnification, and the image (c) shows a SEM image of 5000 times magnification.

FIG. 4 shows a result of XRD of an embodiment.

FIG. 5 shows a result of XRD of an embodiment.

FIG. 6 shows a result of XRD of an embodiment.

FIG. 7 shows a schematic diagram of a film-formation apparatus used in an embodiment. The film-formation apparatus shown in FIG. 7 differs from a film-formation apparatus shown in FIG. 1 in the point that the film-formation apparatus shown in FIG. 7 does not include a film-formation chamber.

FIG. 8 shows a measurement result of a fluorescence spectrum of the hole-transport layer for an organic light-emitting element with a substrate obtained in an embodiment.

FIG. 9 shows a measurement result of a fluorescence spectrum of the light-emitting layer attached to the substrate obtained in an embodiment.

### DESCRIPTION OF EMBODIMENTS

According to an embodiment of a method of forming a film of the present invention, the method includes turning a raw-material solution containing an aprotic solvent by atomization into a mist or droplets (in atomization and/or droplet-formation), carrying the mist or droplets by a carrier gas onto a base (in carrying the mist or droplets), and forming the film on the substrate by causing a thermal reaction of the mist or droplets (in film-formation). Hereinafter, embodiments in each step will be described.

(In Atomization and/or Droplet-Formation)

In the atomization and/or droplet-formation, a raw-material solution is turned into a mist or droplets by atomization. Atomization of a raw-material solution is not limited to a particular way, and may use a conventional way, however, according to an embodiment of a present invention, turning a raw-material solution into a mist or droplets using ultrasonic waves is preferable. Mist or droplets obtained using ultrasonic waves have the initial velocity that is zero, and float in the air. For example, since the mist or droplets floating in the air is carriable as a gas, it is preferable to avoid damage caused by the collision energy without being blown like a spray. The size of droplets is not limited to a particular size, and may be a few mm, however, preferably to be 50 μm or less, and further preferably to be a size in a range of 100 nm to 10 μm.

### (Raw-Material Solution)

The raw-material solution contains an aprotic solvent and is not particularly limited as long as it can be atomized to obtain a mist or droplets. The raw-material solution may contain an inorganic material. The raw-material solution may contain an organic material. In addition, the raw-material solution may contain both inorganic and organic materials.

The aprotic solvent is not particularly limited as long as the aprotic solvent is a solvent that is difficult to donate a proton, but in the present invention, it is preferably a solvent represented by the following Chemical Formula (1) or Chemical Formula (2).

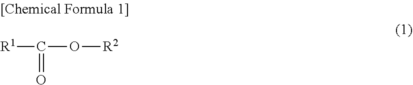

(In the Chemical Formula (1), R¹ may be identical to R². Also, R¹ may be different from R². R¹ represents one selected from among a hydrogen atom, a halogen atom, an optionally substituted hydrocarbon group, and an optionally substituted heterocyclic group. R² represents one selected from among a hydrogen atom, a halogen atom, an optionally substituted hydrocarbon group, and an optionally substituted heterocyclic group. R¹ and R² may be taken together to form a ring.)

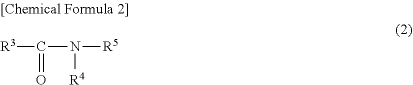

(In the Chemical Formula, R³, R⁴ and R⁵ may be optionally identical to one another. Also, R³, R⁴ and R⁵ may be optionally different from one another. R³ represents one selected from among a hydrogen atom, a halogen atom, an optionally substituted hydrocarbon group, and an optionally substituted heterocyclic group. R⁴ represents one selected from among a hydrogen atom, a halogen atom, an optionally substituted hydrocarbon group, and an optionally substituted heterocyclic group. R⁵ represents one selected from among a hydrogen atom, a halogen atom, an optionally substituted hydrocarbon group, and an optionally substituted heterocyclic group. Two arbitrary groups selected from among R³, R⁴ and R⁵ may be bonded to each other to form a ring.)

As the “halogen atom”, for example, a fluorine atom, a chlorine atom, a bromine atom, an iodine atom may be named.

Examples of the “sub stituent” according to embodiments of the present invention include a hydrocarbon group which optionally has a substituent, a heterocyclic group which optionally has a substituent, a halogen atom, a halogenated hydrocarbon group, —OR^{1a} (“R^{1a}” represents a hydrogen atom, a hydrocarbon group which optionally has a substituent, or a heterocyclic group which optionally has a substituent), —SR^{1b} (“R^{1b}” represents a hydrogen atom, a hydrocarbon group which optionally has a substituent, or a heterocyclic group which optionally has a substituent), an acyl group which optionally has a substituent, an acyloxy group which optionally has a sub stituent, an alkoxycarbonyl group which optionally has a substituent, an aryloxycarbonyl group which optionally has a substituent, an alkylenedioxy group which optionally has a substituent, a nitro group, an amino group, a substituted amino group, a cyano group, a sulfo group, a substituted silyl group, a hydroxyl group, a carboxy group, an alkoxythiocarbonyl group which optionally has a substituent, an aryloxythiocarbonyl group which optionally has a substituent, an alkylthiocarbonyl group which optionally has a substituent, an arylthiocarbonyl group which optionally has a substituent, a carbamoyl group which optionally has a substituent, a substituted phosphino group, an aminosulfonyl group, an alkoxysulfonyl group, and an oxo group.

Examples of the “hydrocarbon group” include a hydrocarbon group and a substituted hydrocarbon group. As the “hydrocarbon group”, for example, an alkyl group, an aryl group, and an aralkyl group may be named.

The alkyl group is preferably a linear alkyl group having 1 to 20 carbon atoms, a branched alkyl group having 1 to 20 carbon atoms, and a cyclic alkyl group having 1 to 20 carbon atoms. Specific examples of the alkyl group include methyl, ethyl, n-propyl, 2-propyl, n-butyl, 1-methylpropyl, 2-methylpropyl, tert-butyl, n-pentyl, 1-methylbutyl, 1-Ethylpropyl, tert-pentyl, 2-methylbutyl, 3-methylbutyl, 2,2-dimethylpropyl, n-hexyl, 1-methylpentyl, 1-ethylbutyl, 2-methylpentyl, 3-methylpentyl, 4-methylpentyl, 2-methyl pentane, 2-methylpentan-3-yl, 3,3-dimethylbutyl, 2,2-dimethylbutyl, 1,1-dimethylbutyl, 1,2-dimethylbutyl, 1,3-dimethylbutyl, 2,3-dimethylbutyl, 1-ethylbutyl, 2-ethylbutyl, heptyl, octyl, nonyl, decyl, undecyl, dodecyl, tridecyl, tetradecyl, pentadecyl, hexadecyl, heptadecyl, octadecyl, nonadecyl, eicosyl, cyclopropyl, cyclobutyl, cyclopentyl and cyclohexyl. The alkyl group is preferably an alkyl group having 1 to 10 carbon atoms, still further preferably an alkyl group having 1 to 6 carbon atoms, and particularly preferably an alkyl group having 1 to 4 carbon atoms.

The aryl group is preferably an aryl group having 6 to 20 carbon atoms. Specific examples of the aryl group include phenyl, indenyl, pentalenyl, naphthyl, azulenyl, fluorenyl, phenanthrenyl, anthracenyl, acenaphthylenyl, biphenylenyl, naphthacenyl and pyrenyl. Among them, an aryl group having 6 to 14 carbon atoms is further preferable.

The aralkyl group is preferably an aralkyl group having 7 to 20 carbon atoms. Specific examples of the aralkyl group include benzyl, phenethyl, 1-phenylpropyl, 2-phenylpropyl, 3-phenylpropyl, 1-phenylbutyl, 2-phenylbutyl, 3-phenylbutyl, 4-phenylbutyl, 1-phenylpentylbutyl, 2-phenylpentylbutyl, 3-phenylpentylbutyl, 4-phenylpentylbutyl, 5-phenylpentylbutyl, 1-phenylhexylbutyl, 2-phenylhexylbutyl, 3-phenylhexylbutyl, 4-phenylhexylbutyl, 5-phenylhexylbutyl, 6-phenylhexylbutyl, 1-phenylheptyl, 1-phenyloctyl, 1-phenylnonyl, 1-phenyldecyl, 1-phenylundecyl, 1-phenyldodecyl, 1-phenyltridecyl and 1-phenyl-tetradecyl. Among them, the aralkyl group is further preferably an aralkyl group having 7 to 12 carbon atoms.

As a substituent that the “hydrocarbon group” may have, the examples of the “substituent” mentioned above are referred to. Specific examples of hydrocarbon group having a substitute include a substituted alkyl group such as trifluoromethyl and methoxymethyl, tolyl (eg, 4-methylphenyl), xylyl (eg, 3,5-dimethylphenyl), 4-methoxy-3,5-dimethylphenyl, a substituted aryl group such as 4-methoxy-3,5-di-t-butylphenyl, and a substituted aralkyl group.

The “heterocyclic group optionally having a substituent” include a heterocyclic group and a substituted heterocyclic group. Examples of the heterocyclic group include an aliphatic heterocyclic group and an aromatic heterocyclic group. The aliphatic heterocyclic group may be three- to eight-membered, monocyclic aliphatic heterocyclic group, a polycyclic aliphatic heterocyclic group, or a fused-ring aliphatic heterocyclic group. The aliphatic heterocyclic group may be preferably five - or six-membered, monocyclic aliphatic heterocyclic group, a polycyclic aliphatic heterocyclic group, or a fused-ring aliphatic heterocyclic group. The aliphatic heterocyclic group includes, for example, an aliphatic heterocyclic group having 2 to 14 carbon atoms and containing at least one heteroatom, preferably heteroatom(s) such as one to three nitrogen atom(s), oxygen atom(s), and/or sulfur atom(s). Specific examples of the aliphatic heterocyclic group include a pyrrolidyl-2-one, a piperidyl group, a tetrahydrofuryl group, a tetrahydropyranyl group, a thiolanyl group, and a succinimidyl group.

The aromatic heterocyclic group may be a monocyclic group having three to eight members or preferably a monocyclic group having five or six members, and the monocyclic group, for example, having two to 15 carbon atoms and containing at least one heteroatom, preferably heteroatom(s) that may be one to three nitrogen atom(s), oxygen atom(s) and/or sulfur atom(s). Also, the aromatic heterocyclic group may be a polycyclic group having three to eight members or preferably a polycyclic group having five or six members, and the polycyclic group, for example, having two to 15 carbon atoms and containing at least one heteroatom, preferably heteroatoms that may be one to three nitrogen atom(s), oxygen atom(s) and/or sulfur atom(s). The aromatic heterocyclic group may be a fused ring heterocyclic group having three to eight members or preferably a fused ring heterocyclic group having five or six members, and the fused ring heterocyclic group, for example, having two to 15 carbon atoms and containing at least one heteroatom, preferably heteroatoms that may be one to three nitrogen atom(s), oxygen atom(s) and/or sulfur atom(s). For more details, specific examples of the aromatic heterocyclic group include furyl, thienyl, pyrrolyl, oxazolyl, isoxazolyl, thiazolyl, isothiazolyl, imidazolyl, pyrazolyl, 1,2,3-oxadiazolyl, 1,2,4-oxadiazolyl, 1,3,4-oxadiazolyl, furazanyl, 1,2,3-thiadiazolyl, 1,2,4-thiadiazolyl, 1,3,4-thiadiazolyl, 1,2,3-triazolyl, 1,2,4-triazolyl, tetrazolyl, pyridyl, pyridazinyl, pyrimidinyl, pyrazinyl, triazinyl, benzofuranyl, isobenzofuranyl, benzo [b] thienyl, indolyl, isoindolyl, 1H-indazolyl, benzimidazolyl, benzoxazolyl, 1,2-benzisoxazolyl, benzothiazolyl, benzopyrani, 1,2-benzisothiazolyl, 1H-benzotriazolyl, quinolyl, isoquinolyl, cinnolinyl, quinazolinyl, quinoxalinyl, phthalazinyl, naphthyridinyl, purinyl, pteridinyl, carbazolyl, α-carbolinyl, β-carbolinyl, γ-carbolinyl, acridinyl, phenoxazinyl, phenothiazinyl, phenazinyl, phenoxathiinyl, thianthrenyl, phenanthridinyl, phenanthrolinyl, indolizinyl, pyrrolo [1,2-b] pyridazinyl, pyrazolo [1,5-a] pyridyl, imidazo [1,2-a] pyridyl, imidazo [1,5-a] pyridyl, imidazo [1,2-b] pyridazinyl, imidazo [1,2-a] pyrimidinyl, 1,2,4-triazolo [4,3-a ] pyridyl, 1,2,4-tri asolo [4,3-b] pyridazinyl, benzo [1,2,5] thiadiazolyl, benzo [1,2,5] oxadiazolyl, and futaruimino group.

As a substituent that the “heterocyclic group” may have, the examples of the “substituent” mentioned above are referred to.

According to embodiments of the present invention, it is preferable that R¹ and R² in the Chemical Formula (1) are bonded to form a ring. Also, it is preferable that two selected from among R³, R⁴, and R⁵ are bonded to form a ring in the Chemical Formula (2). The ring formed by R¹ and R² that are bonded to be a five- to 20-membered ring that may contain heteroatom(s) such as one to three oxygen atom(s), nitrogen atom(s), and sulfur atom(s) as constituent atoms forming the ring, for example. The ring formed by two selected from among R³, R⁴, and R⁵ that are bonded to be a five- to 20-membered ring that may contain heteroatom(s) such as one to three oxygen atom(s), nitrogen atom(s), and sulfur atom(s), for example. As a ring that is preferable, for example, may be a monocyclic ring such as a cyclopentane ring, a cyclohexane ring, a cycloheptane ring, a cyclooctane ring, a cyclodecane ring, a cyclododecane ring, a cyclotetradecane ring, a cyclopentadecane ring, a cyclohexadecane ring, and a cycloheptadecane ring, or a fused ring such as a dihydronaphthalene ring, an indene ring, an indane ring, a dihydroquinoline ring and a dihydroisoquinoline ring. The ring that is preferable mentioned above may usually include one or two heteroatom(s) that may be oxygen atom(s), nitrogen atom(s) and/or sulfur atom(s). Furthermore, the ring that is preferable may be substituted with a hydrocarbon group, a heterocyclic group, an alkoxy group, or a substituted amino group, for example. Specific examples of the hydrocarbon group may be a hydrocarbon group mentioned above. Also, specific examples of the heterocyclic group may be a heterocyclic group mentioned above.

The alkoxy group may be linear. The alkoxy group may be branched. The alkoxy group may be cyclic. As the alkoxy group, for example, an alkoxy group having one to six carbon atoms is named. Specific examples of the alkoxy group include a methoxy group, an ethoxy group, an n-propoxy group, an isopropoxy group, butoxy group, a 2-butoxy group, an isobutoxy group, a tert-butoxy group, an n-pentyloxy group, a 2-methylbutoxy group, a 3-methylbutoxy group, a 2,2-dimethylpropyloxy group, n-hexyloxy group, 2-methylpentyloxy group, 3-methylpentyloxy group, 4-methylpentyloxy group, 5-methylpentyloxy group, cyclohexyloxy group, methoxymethoxy group, and 2-ethoxyethoxy group.

As a substituted amino group, an amino group in that one or two hydrogen atom(s) is (are) substituted by substituent(s). Specific examples of a substituent of the substituted amino group include a hydrocarbon group (for example, an alkyl group etc.), an aryl group, an aralkyl group, an acyl group, an alkoxycarbonyl group, an aryloxycarbonyl group, and an aralkyloxycarbonyl group, for example. Specific examples of an amino group substituted with an alkyl group, that is, an alkyl group-substituted amino group include, for example, an N-methylamino group, N, N-dimethylamino group, N, N-diethylamino group, N, N-diisopropylamino group, an N-methyl-N-isopropylamino group, a mono of N-cyclohexylamino group, and a dialkylamino group. Specific examples of an amino group substituted with an aryl group, that is, the aryl group-substituted amino group include, for example, an N-phenylamino group, N, N-diphenylamino group, N-naphthylamino group, mono-N-methyl-N-phenylamino group, and a diarylamino group. Specific examples of the amino group substituted with an aralkyl group, that is, the aralkyl group-substituted amino group include an N-benzylamino group, a mono-N, N-dibenzylamino group and di-aralkylamino group. Also, a substituted amino group such as a N-benzyl-N-methylamino group may be named. Specific examples of the amino group substituted with an acyl group, that is, acylamino group include a formylamino group, an acetylamino group, a propionylamino group, a pivaloylamino group, a pentanoylamino group, a hexanoylamino group, and a benzoylamino group. Specific examples of the amino group substituted with an alkoxycarbonyl group, that is, an alkoxycarbonylamino group, include a methoxycarbonylamino group, an ethoxycarbonylamino group, an n-propoxycarbonylamino group, an n-butoxycarbonylamino group, a tert-butoxy carbonylamino group, a pentyloxycarbonylamino group, and a hexyloxycarbonylamino group. Specific examples of the amino group substituted with an aryloxycarbonyl group, that is, an aryloxycarbonylamino group, include an amino group in which one hydrogen atom of the amino group is substituted with the above-described aryloxycarbonyl group, and specific examples of the aryloxycarbonyl group include a phenoxycarbonylamino group and a naphthyloxycarbonylamino group, for example. Specific examples of the amino group substituted with an aralkyloxycarbonyl group, that is, an aralkyloxycarbonylamino group, include a benzyloxycarbonylamino group.

In embodiments of the present invention, the aprotic solvent is preferably a solvent represented by the Chemical Formula (1). The aprotic solvent is further preferably an aliphatic cyclic ester that may be a lactone or a lactam. Examples of the aliphatic cyclic ester include lactide, glycolide, ε-caprolactone, p-dioxanone, trimethylene carbonate, an alkyl derivative of trimethylene carbonate, γ-valerolactone, β-butyrolactone, γ-butyrolactone, ε-decalactone, hydroxyvalerate, pivalolactone, α, α-diethylpropiolactone, ethylene carbonate, ethylene oxalate, γ-butyrolactam, and ε-caprolactam. According to embodiments of the present invention, the raw-material solution is preferably a precursor solution with a perovskite structure. The perovskite structure of the precursor solution is not particularly limited, as long as the precursor solution has a perovskite structure. The perovskite structure may be a known perovskite structure. The perovskite structure may be of an inorganic material. Also, the perovskite structure may be of an organic material. According to embodiments of the present invention, the perovskite structure is preferably of an organic-inorganic composite material. Examples of the organic-inorganic composite material include chemical compounds shown in the following formula (I) and the following formula (II).

CH₃NH₃M¹X₃ (I)

IN the formula (I), M¹ is a divalent metal ion, and X may be F, Cl, Br or I.

(R⁶NH₃)₂M¹X₄ (II)

In the formula (II), R⁶ is an alkyl group, an alkenyl group, an aralkyl group, an aryl group, a heterocyclic group or an aromatic heterocyclic group, and has two or more carbon atoms, M¹ is a divalent metal ion, and X may be F, Cl, Br or I.

According to embodiments of the present invention, the organic-inorganic composite material is preferably a substituted ammonium lead halide. Examples of the substituted ammonium lead halide include (CH₃NH₃)PbI₃ (methyl ammonium lead iodide), (C₆H₅C₂H₄NH₃)₂PbI₄ (phenethyl ammonium lead iodide), (C₁₀H₇CH₂NH₃)₂PbI₄ (naphtylmethylammonium lead ionide), and (C₆H₁₃NH₃)₂PbI₄ (hexylammonium lead iodide). From viewpoints of a possibility of formation of perovskite structure, intramolecular symmetry, dielectric constant, and dipole moment, for example, (CH₃NH₃)PbI₃ (methyl ammonium lead iodide) is preferable. The substituted ammonium lead halide may be one selected from the above-mentioned examples mentioned or may be a combination of two or more of the above-mentioned examples of the substituted ammonium lead halide. According to an embodiment of the present invention, the raw-material solution preferably contains an organometal halide compound. Also, according to an embodiment of the present invention, the raw-material solution preferably contains an ammonium compound. The organometal halide compound or ammonium compound that is preferably used for embodiments of the present invention may be a compound represented by the above-mentioned Formula (I) or the above-mentioned Formula (II), for example.

According to embodiments of the present invention, as the raw-material solution, the compound in the form of a complex or salt dissolved or dispersed in an organic solvent or an inorganic solvent such as water may be preferably used. Examples of the form of the complex include an acetylacetonate complex, a carbonyl complex, an ammine complex, and a hydride complex. Examples of the salt form include organic metal salts (for example, metal acetate, metal oxalate, metal citrate, etc.), metal sulfide salts, metal nitrate salts, phosphorylated metal salts, metal halide salts (for example, metal chloride salts, metal bromide salts, metal iodide salts, etc.).

Furthermore, a film according to an embodiment of the present invention may be used for a hole transport layer included in an organic light-emitting element (hereinafter, the hole transport layer of the organic light-emitting element) and/or a lamination of light-emitting layer(s). According to an embodiment of the present invention, the film has a perovskite structure and may include the hole transport layer and/or a light-emitting layer. If the film is supposed to include a hole transport layer and/or a light-emitting layer, the raw-material solution may include a precursor solution of the organic hole transport layer and/or the light-emitting layer. For more details, the raw-material solution may contain an aprotic solution and a precursor of the hole transport layer of the organic light-emitting element and/or a precursor of light-emitting layer.

According to an embodiment of the present invention, in the case that the raw-material solution is a precursor solution of the hole transport layer of the organic light-emitting element, it is preferable that the raw-material solution contains an amine derivative which is a precursor of the hole transport layer of the organic light-emitting element. The amine derivative is not particularly limited as long as it has an amine skeleton, however, according to an embodiment of the present invention, the amine derivative contained in the raw-material solution is preferably an arylamine derivative, because it is possible to form a film efficiently. According to an embodiment of the present invention, the amine derivative contained in the raw-material solution is further preferably a tertiary arylamine derivative. According to an embodiment of the present invention, the amine derivative contained in the raw-material solution is most preferably a benzidine-based amine derivative. Examples of the tertiary arylamine derivative include, for example, 4,4′-bis [N-(1-naphthyl)-N-phenylamino] biphenyl (abbreviation: α-NPD) and N,N′-bis (3-methylphenyl)-N, N′-diphenyl-[l,1′-biphenyl]-4,4′-diamine (abbreviation: TPD), 4,4′,4″-tris (N, N-diphenylamino) triphenylamine (Abbreviation: TDATA), 4,4′, 4″-tris [N-(3-methylphenyl)-N-phenylamino] triphenylamine (abbreviation: MTDATA), N,N′-bis spiro-9,9′-bifluoren-2-yl)-N,N′-diphenylbenzidine (abbreviation: BSPB), N, N′-bis (4-methylphenyl) (p-tolyl)-N,N′ diphenyl-p-phenylenediamine (abbreviation: DTDPPA), 4,4′-bis [N-(4-diphenylaminophenyl)-N-phenylamino] biphenyl (abbreviation: DPAB), 4,4′-bis N-{4-[N′-(3-methylphenyl)-N′-phenylaminol phenyl}-N-phenylamino) biphenyl (abbreviation: DNTPD), 1,3,5-tris [N-(4-diphenylaminophenyl)-N-phenylamino] benzene (abbreviation: DPA 3 B), and a mixture of two or more thereof. Examples of the benzidine-based amine derivatives include 4,4′-bis [N-(1-naphthyl)-N-phenylamino] biphenyl (abbreviation: α-NPD), N,N′-bis (3-methylphenyl)-N,N′-diphenyl-4,4′-diamine (abbreviation: TPD), N,N′-bis (spiro-9,9′-bifluorene)-2-yl-N,N′-diphenylbenzidine (abbreviation: BSPB), and a mixture of two or more thereof. According to embodiments of the present invention, the amine derivative containing α-NPD, which is superior in enhancing solubility into an aprotic solution and facilitating handleability, is preferable, and the amine derivative is further preferably α-NPD. By the way, α-NPD may be referred as NPB, however, embodiments of the present invention are not limited to these names. The amine derivative may be a mixture of two or more amine compounds. Examples of the two or more amine compounds include examples of the amine compounds mentioned as the benzidine-based amine derivatives.

In embodiments of the present invention, in the case that the raw-material solution is a precursor solution of a hole transport layer, the aprotic solvent is preferably a solvent represented by the Chemical Formula (1). The aprotic solvent is further preferably a lactone or a lactam. According to an embodiment of the present invention, the aprotic solvent is most preferably y-butyrolactam.

In embodiments of the present invention, in the case that the raw-material solution is a precursor solution of a light-emitting layer, the raw-material solution preferably contains a metal complex that is a precursor of the light-emitting layer. The metal complex is not particularly limited as long as the metal complex is a metal compound having a metal-carbon bond or a metal complex having a coordinate bond. The metal in the metal complex is not particularly limited but is preferably beryllium, magnesium, aluminum, gallium, zinc, indium, tin, platinum, palladium or iridium. According to an embodiment of the present invention, the metal in the metal complex is further preferably beryllium, aluminum, gallium, zinc, or iridium.

Specific examples of the metal complex include a metal complex having a quinoline skeleton, a metal complex having a benzoquinoline skeleton, a metal complex having a pyridine skeleton, a metal complex having an oxazole skeleton, and a metal complex having a thiazole skeleton. Examples of the metal complex having the quinoline skeleton include tris (8-quinolinolato) aluminum (hereinafter referred to as Alq₃), tris (4-methyl-8-quinolinolato) aluminum (hereinafter referred to as Almq₃), bis (2-methyl-8-quinolinolato)-(4-hydroxy-biphenylyl)-aluminum (hereinafter referred to as BAlq), bis (2-methyl-8-quinolinolato)-4-phenylphenolato-gallium (hereinafter referred to as BGaq). Examples of the metal complex having the benzoquinoline skeleton include bis (10-hydroxybenzo [h]-quinolinato) beryllium (hereinafter referred to as BeBq₂). Examples of the metal complex having the pyridine skeleton include tris (2-phenylpyridine) iridium (hereinafter referred to as Ir (ppy)₃), bis [2-(3,5-bis (trifluoromethyl phenyl) pyridinato-N, C^{2′}] iridium (III) picolinate (hereinafter referred to as Ir (CF₃ppy)₂(pic)), bis [2-(4,6-difluorophenyl) pyridinato-N, C ^{2′}] iridium (III) acetylacetonate (hereinafter referred to as FIr (acac)), bis [2-(4,6-difluorophenyl) pyridinato-N, C² ′)] iridium (III) picolinate (hereinafter referred to as Flr (pic)). Examples of the metal complex having the oxazole skeleton include bis [2-(2-hydroxyphenyl)-benzoxazolato] zinc (hereinafter referred to as Zn (BOX)2). Examples of the metal complex having the thiazole skeleton include bis [2-(2-hydroxyphenyl) benzothiazolato] zinc (hereinafter referred to as Zn (BTZ)₂). The metal complex may be a mixture of two or more metal complexes mentioned above. According to embodiments of the present invention, the metal complex preferably has a quinoline skeleton or a benzoquinoline skeleton, and further preferably has a quinoline skeleton. According to an embodiment of the present invention, the metal complex preferably contains an aluminum quinolinol complex that tends to enhance solubility and handleability with an aprotic solvent, further preferably contains Alq3. It is most preferable that the metal complex is Alq3. The metal complex may be a mixture of two or more metal complexes, and a mixture of two or more of the above-mentioned metal complexes may be named as examples of the two or more metal complexes include.

According to an embodiment of the present invention, in the case that the raw-material solution is a precursor solution of the light-emitting layer, the aprotic solvent is preferably a solvent represented by the Chemical Formula (1), further preferably a lactone or a lactam, and the aprotic solvent is most preferably γ-butyrolactone.

Also, an additive that may be a hydrohalic acid or an oxidant, for example, may be added into the raw-material solution. Examples of the hydrohalic acid include a hydrobromic acid, a hydrochloric acid, and a hydriodic acid, and among the examples, a hydrobromic acid or a hydriodic acid is preferable. Examples of the oxidant include peroxides such as hydrogen peroxide (H₂O₂), sodium peroxide (Na₂O₂), barium peroxide (BaO₂), benzoyl peroxide (C₆H₅CO)₂O₂, and organic peroxides such as hypochlorous acid (HCIO), perchloric acid, nitric acid, ozone water, peracetic acid, and nitrobenzene, and among the examples, hydrogen peroxide (H₂O₂) is preferable.

(Carrying a Mist into a Film-Formation Part)

In carrying a mist into a film-formation part (that may be a film-formation chamber, for example), the mist or droplets are carried by a carrier gas into a film-formation part onto a substrate that is placed in the film-formation part. The carrier gas is not particularly limited as long as the carrier gas does not interfere with an object of the present invention, and examples of the carrier gas include oxygen, ozone, an inert gas such as nitrogen and argon, or a reducing gas such as hydrogen gas and forming gas. The carrier gas may be one selected from among the examples of the carrier gas. Also, the carrier gas may be two or more gases selected from among the examples of the carrier gas. Furthermore, a dilution gas with a reduced flow rate (for example, a 10-fold dilution gas) may be used as a second carrier gas in addition to a carrier gas. Furthermore, the carrier gas may be supplied to a mist at a first place and also may be supplied to the mist at a second place or at more places. The flow rate of the carrier gas is not particularly limited, but the flow rate is preferably 0.01 to 20 L/min, and further preferably 1 to 10 L/min. Also, in the case of using a dilution gas, the flow rate of the dilution gas is preferably 0.001 to 2 L/min, and further preferably 0.1 to 1 L/min.

### (Forming a Film)

In forming a film, the film is to be formed on a base by causing a reaction of the mist adjacent to the base. The reaction may be a reaction due to drying the mist adjacent to the base, but thermal reaction of the mist due to heat is preferable. In the thermal reaction, as long as the mist or droplets cause a thermal reaction to form a film and an object of the present inventive subject matter is not interfered with, conditions of reaction are not particularly limited. In forming a film, the thermal reaction is basically carried out at 250° C. or less, and according to an embodiment of the present invention, the thermal reaction is preferably carried out at 150° C. or less, and further preferably at 140° C. or less. According to an embodiment of the present invention, since forming a film favorably on a base even at a low temperature is possible, a base of various materials is able to be used to form a film. In particular, the film, which is formed with a close adhesion and with less thermal influence on the base, is able to exert primal properties of the film. The lower limit of the temperature for thermal reaction is not particularly limited unless it hinders an object of the present invention, but the lower limit of the temperature of the thermal reaction is preferably 100° C. or higher, and further preferably 110° C. or higher. The thermal reaction may be carried out in any such as in a vacuum, in a non-oxygen atmosphere, in a reducing gas atmosphere, and in an oxygen atmosphere, as long as an object of the present invention is not interfered with, however, the thermal reaction may be preferably carried out in a non-oxygen atmosphere or in oxygen atmosphere. Furthermore, the thermal reaction may be carried out under any atmospheric pressure, under increased pressure, or under reduced pressure, however, according to embodiments of the present invention, the thermal reaction is preferably carried out under atmospheric pressure. Note that the film thickness can be set by adjusting the film formation time.

### (Base)

The base is not particularly limited as long as the base is able to support a film to be formed on the base. The base may be a flexible base. The base may be made of a material of an organic compound or a material of an inorganic compound. The base may have a porous structure. The base may have a plate shape, a circular plate shape, a shape of fiber, a shape of a stick, a shape of a round pillar, a shape of a square pillar, a shape of a tube, a shape of a spiral, a shape of sphere, and/or a shape of ring. According to an embodiment of the present invention, the base is able to have various shapes. According to an embodiment of the present invention, the base may preferably have a shape of substrate. The base may have a thickness that is preferably 0.5 μm to 100 mm. The base may be further preferably 1 μm to 10 mm in thickness.

The base may be not particularly limited as long as the base is in the form of a plate and serves as a support of a film to be formed on the base. The base may be an electrically-insulating substrate, a semiconductor substrate, a metal substrate or an electrically-conductive substrate, and also a base including at least one of a metal film, a semiconductor film, an electrically-conductive film and an electrically-insulating film partly or entirely on a surface of the base may be used. According to an embodiment of the present invention, the substrate is preferably a glass substrate including at least one film selected from among a metal film, a semiconductor film, an electrically-conductive film, and an electrically-insulating film and arranged on a surface of the glass substrate. As a constituent metal of the metal film on the glass substrate, one or more metals is(are) selected from among gallium, iron, indium, aluminum, vanadium, titanium, chromium, rhodium, nickel, cobalt, zinc, magnesium, calcium, silicon, yttrium, strontium and barium, for example. Examples of a constituent material of the semiconductor film including a chemical element such as silicon and germanium, a chemical compound containing an element selected from among elements of Group 3 to Group 5 and elements of Group 13 to Group 15 in the periodic table, a metal oxide, a metal sulfide, a metal selenide and a metal nitride are named. Examples of a constituent material of the electrically-conductive film include tin-doped indium oxide (ITO), fluorine-doped indium oxide (FTO), antimony-doped tin oxide (ATO), zinc oxide (ZnO), aluminum doped zinc oxide (AZO), gallium-doped zinc oxide (GZO), tin oxide (SnO₂), indium oxide (In₂O₃), tungsten oxide (WO₃). According to an embodiment of the present invention, the electrically-conductive film including an electrically-conductive oxide is preferable, and further preferably is a tin-doped indium oxide (ITO) film. As a constituent material of the electrically-insulating film, examples include aluminum oxide (Al₂O₃), titanium oxide (TiO₂), silicon oxide (SiO₂), silicon nitride (Si₃N₄), silicon oxynitride (Si₄O₅N₃), and an electrically-insulating film made of an electrically-insulating oxide is preferable. The electrically-insulating film is further preferably a titania film.

In forming the metal film, the semiconductor film, the electrically-conductive film, and/or the electrically-insulating film, the method of forming the metal film, the semiconductor film, the electrically-conductive film, and/or the electrically-insulating film is not particularly limited, and a known method may be used. Examples of the method of forming the metal film, the semiconductor film, the electrically-conductive film, and/or the electrically-insulating film include a mist CVD method, a sputtering method, a CVD (Chemical Vapor Deposition) method, an SPD (Spray Pyrolysis Deposition) method, an evaporation method, an ALD (Atomic Layer Deposition), and a coating method such as dipping, dropping, a doctor blade coating, ink jet coating, spin coating, brush coating, spray coating, roll coating, air knife coating, curtain coating, wire-bar coating, and gravure coating.

According to an embodiment of the present invention, the electrically-conductive film or the electrically-insulating film is preferably formed on a base that is a substrate. According to an embodiment of the present invention, an electrically-conductive film is further preferably arranged on the substrate and an electrically-insulating film is arranged on the electrically-conductive film. Also, according to an embodiment of the present invention, the base preferably includes a tin-doped indium oxide film or a titania film. Furthermore, according to an embodiment of the present invention, the base further preferably includes a tin-doped indium oxide film and a titania film.

In embodiments of the present invention, the film may be formed directly on the base, or may be formed via another layer such as a buffer layer or a stress-relaxation layer on the base. A method of forming another layer such as the buffer layer and the stress-relaxation layer is not particularly limited, and a known method may be used, however, according to an embodiment of the present invention, a mist CVD method is preferable.

In the case of forming a perovskite film as the above-mentioned, it is possible to form a perovskite film having a perovskite structure sufficient in quality easily even without performing an annealing treatment. In addition, it is possible to adjust the film thickness of the perovskite film easily by increasing or decreasing the film-formation time.

Note that the perovskite film may be useful for a photoelectric-conversion element, for example. According to an embodiment of the present invention, a perovskite film that is separated from the base by use of a known method may be used for a photoelectric-conversion element. Also, according to an embodiment of the present invention, a perovskite film with a base on that the perovskite film is arranged is able to be used for a photoelectric-conversion element

According to an embodiment of the present invention, a perovskite film favorably used in a photoelectric-conversion element is explained as follows.

In the embodiment that the perovskite film is used for a photoelectric-conversion element, the base is preferably a transparent substrate. The transparent substrate further preferably includes an electrode formed on a surface of the transparent substrate to be an electrically-conductive substrate. The transparent substrate has a light transmittance that is 10% or more, preferably 50% or more, and further preferably 80% to 100%, when measured according to JIS K 7361-1: 1997.

The transparent substrate may be a rigid substrate (for example, a glass substrate or an acrylic substrate) and a flexible substrate (for example, a film substrate). Either the rigid substrate or the flexible substrate is suitably used as a transparent substrate in embodiments of the present invention. The transparent substrate may be preferably a rigid substrate from the viewpoint of heat resistance. Types of glass are not particularly limited.

Examples of the flexible substrate include a film of polyethylene terephthalate (PET), a film of polyethylene naphthalate, a film of polyester-based resin such as modified polyester, a polyethylene (PE) resin film, a polypropylene (PP) resin film, a polystyrene resin film, a film of polyolefin resin such as cyclic olefin-based resin, a film of polyvinyl chloride, a film of vinyl-based resin such as polyvinylidene chloride, a film of polyvinyl acetal resin such as polyvinyl butyral (PVB), a polyether ether ketone (PEEK) resin film, a polysulfone (PSF) resin film, a polyethersulfone (PES) resin film, a polycarbonate (PC) resin film, a polyamide resin film, a polyimide resin film, an acrylic resin film, a triacetyl cellulose (TAC) resin film. Instead of the above-mentioned resin films, an inorganic glass film may be used as a substrate. Also, nanofibers such as carbon nanofibers, cellulose nanofibers, and cyclodextrin nanofibers are preferably used as a flexible substrate.

In the case that the perovskite film is used in a photoelectric-conversion element, a first electrode, an electron transport layer (also mentioned as “the electron transport layer of the photoelectric-conversion element” as follows), a photoelectric-conversion layer including a semiconductor and a perovskite structure, a hole transport layer (also mentioned as “the hole transport layer of the photoelectric-conversion element), and a second electrode are arranged on the transparent substrate to manufacture a photoelectric-conversion element.

The first electrode may be arranged between the transparent substrate and the photoelectric-conversion layer and may be arranged on a first side that is an opposite side of a second side which light enters, however, in embodiments of the present invention, the arrangement of the first electrode is not particularly limited. The first electrode preferably has a light transmittance that is 60% or more, further preferably 80% or more, and most preferably 90% to 100%. The light transmittance may be the same as described in the description of the transparent substrate.

The material forming the first electrode is not particularly limited and may be a known material. For example, metals such as platinum, gold, silver, copper, magnesium, aluminum, rhodium, and indium or alloys of two or more metals selected from among platinum, gold, silver, copper, magnesium, aluminum, rhodium, and indium. Also, the material forming the first electrode may be a metal oxide. Examples of the metal oxide include SnO₂, CdO, ZnO, and CTO (CdSnO₃, Cd₂SnO₄, CdSnO₄), In₂O₃, and CdIn₂O₄. Among the metals mentioned above as a material forming the first electrode, gold, silver or magnesium or an alloy thereof may be preferably used. To obtain a light-transmitting property, a grid-patterned film with opening(s) or a film with particles or nanowires dispersed in or applied to may be preferably used. Also, as the metal oxide, one or more additive(s)-added composite (doping) materials are able to be selected from among Sn, Sb, F and Al. Further preferably, an electrically-conductive metal oxide such as Sn-doped In₂O₃(ITO), Sb-doped SnO₂, and F-doped SnO₂(FTO) may be named, and above all, FTO is most preferable due to thermal resistance. The amount of coating a material as the first electrode is not particularly limited, but the amount of 1 g to 100 g per 1m² of the substrate would be preferable.

The method of forming a first electrode, it is not particularly limited, as long as an object of the present invention is not interfered with, and a known method may be used. Examples of the method of forming a first electrode include a mist CVD method, a sputtering method, a CVD (Chemical Vapor Deposition) method, an SPD (Spray Pyrolysis Deposition) method, an evaporation method, an ALD (atomic layer deposition), and a coating method such as dipping, dropping, a doctor blade coating, ink jet coating, spin coating, brush coating, spray coating, roll coating, air knife coating, curtain coating, wire-bar coating, and gravure coating. Note that the first electrode is preferably an electrically-conductive transparent substrate arranged on a transparent substrate. The average thickness of the electrically-conductive transparent substrate is not limited but preferably in a range of 0.1 mm to 5 mm. Also, the electrically-conductive transparent substrate has a surface resistance that may be 50 Ω/□ or less, further preferably 20 Ω/□ or less, and most preferably 10 Ω/□ or less. Since the lower limit of the surface resistance of the electrically-conductive transparent substrate is preferably as low as possible, there is no particular need to specify it, but the lower limit would be 0.01 Ω/□ or more. The preferable range of the light transmittance of the electrically-conductive transparent substrate would be the same as the above-mentioned preferable range of the light transmittance of the transparent substrate.

The electron transport layer of the photoelectric-conversion element is usually in the form of a film (or layer) to prevent a short circuit, as a sealing and/or for a rectification, and is disposed between the first electrode and the photoelectric-conversion layer (semiconductor layer). The electron transport layer for the photoelectric-conversion element is preferably with a porous structure. When the porosity of the electron transport layer of the photoelectric-conversion element is C [%] and the porosity of the semiconductor layer is D [%], D/C is, for example, about 1.1 or more, D/C is preferably 5 or more, and most preferably is 10 or more. Since the upper limit of D/C is preferably as high as possible, it is not particularly limited, but the upper limit would be 1000 or less. Thus, the electron transport layer of the photoelectric-conversion element and the semiconductor layer can exert functions of the photoelectric-conversion element and the semiconductor layer more suitably. Note that the electron transport layer of the photoelectric-conversion element is usually formed on the first electrode. More specifically, the electron transport layer of the photoelectric-conversion element is preferably a dense layer, and the porosity C of the electron transport layer is preferably 20% or less, further preferably 5% or less, and most preferably 2% or less. As a result, an occurrence of a short circuit tends to be suppressed, and rectification tends to be improved. Here, the lower limit of the porosity of the electron transport layer of the photoelectric-conversion element is preferably as small as possible, so the lower limit of the porosity of the electron transport layer is not particularly limited, but it would be 0.05% or more.

The average thickness (layer thickness) of the electron transport layer of the photoelectric-conversion element is preferably, for example, 0.001 to 10 μm, and further preferably 0.005 to 0.5 μm. Accordingly, the above-mentioned effect tends to be further enhanced.

As a constituent material of the electron transport layer of the photoelectric-conversion element is not particularly limited, but an n-type semiconductor may be used. In the case that the constituent material of the electron transport layer is an inorganic material, examples of the constituent material include zinc, niobium, tin, titanium, vanadium, indium, tungsten, tantalum, zirconium, molybdenum, manganese, iron, copper, nickel, iridium, rhodium, chromium, ruthenium, an oxide of the above-mentioned inorganic material, an oxide semiconductor such as α-gallium oxide, β-gallium oxide, and IGZO, a nitride semiconductor such as GaN, a semiconductor containing silicon such as SiC, a perovskite such as strontium titanate, calcium titanate, barium titanate, magnesium titanate, and strontium niobite, a composite oxide of the above-mentioned inorganic materials, and a mixture of oxide of the above-mentioned inorganic materials, and one or more combinations of metal compounds such as CdS, CdSe TiC, Si₃N₄, SiC, and BN. Furthermore, in the case that the constituent material of the electron transport layer is an organic material, examples of the constituent material include fullerene, a derivative of fullerene (for example, phenyl-C61-butyric acid methyl ester ([60] PCBM), phenyl-C61-butyric acid n-butyl ester ([60] PCBnB), phenyl-C61-butyric acid isobutyl ester ([60] PCBiB), phenyl-C-61-butyric acid n-hexyl ester ([60] PCBH), phenyl-C-61-butyric acid n-octyl ester ([60] PCBO), diphenyl-C62-bis (butyric acid methyl ester) (bis [60] PCBM), phenyl-C71-butyric acid methyl ester ([70] PCBM), phenyl-C85-butyric acid methyl ester ([84] PCBM), thienyl-C61-butyric acid methyl ester ([60] ThCBM), C60 pyrrolidine tris acid, C60 pyrrolidine tris acid ethyl ester, N-Methylfulleropyrrolidine (MP-C60), (1,2-methanofullerene C60)-61-carboxylic acid, (1,2-methanofullerene C60)-61-carboxylic acid t-butyl ester), octaazaporphyrin, a perfluoro compound in which a hydrogen atom of a p -type organic semiconductor compound is substituted with a fluorine atom (examples include perfluoropentacene and perfluorophthalocyanine), an aromatic carboxylic acid anhydride such as naphthalene tetracarboxylic acid anhydride, naphthalene tetracarboxylic acid diimide, perylenetetracarboxylic acid anhydride, and perylene tetracarboxylic acid diimide, and a polymer compound of the aromatic carboxylic acid anhydride containing an imide compound as a skeleton.

For example, in the case that a hole transport layer of a photoelectric-conversion element is a p-type semiconductor and a metal is used for an electron transport layer of the photoelectric-conversion element, it is preferable to use the electron transport layer having a function value, which is smaller than a function value of the hole transport layer and makes a Schottky contact. Further, for example, in the case that a metal oxide is used for the electron transport layer of the photoelectric-conversion element, it is preferable to use an electron transport layer that is in contact with a transparent electrically-conductive layer and an ohmic electrode, and the electron transport layer in that the energy level of the conduction band is lower than the energy level of the porous semiconductor layer. Also, as a component material of the electron transport layer, selecting an oxide is able to enhance efficiency of electron transfer from a porous semiconductor layer (photoelectric-conversion layer) to an electron transport layer of a photoelectric-conversion layer. Among them, a titanium oxide layer containing titanium oxide as a major component and having an electrical conductivity equivalent to an electrical conductivity of a semiconductor layer (photoelectric-conversion layer) is preferable for an electron transport layer of a photoelectric-conversion layer. In this case, the titanium oxide layer may be either a titanium oxide layer with an anatase structure or a titanium oxide layer with a rutile structure that is comparatively high in dielectric constant.

The method of forming the electron transport layer of the photoelectric-conversion element is not particularly limited as long as the method does not interfere with an object of the present invention, and a known method may be used. Examples of the method for forming the electron transport layer of the photoelectric-conversion element include a mist CVD method, a sputtering method, a CVD (Chemical Vapor Deposition) method, an SPD (Spray Pyrolysis Deposition) method, and a vapor deposition method, an ALD (Atomic Layer Deposition) method, a coating method such as dipping, dripping, doctor blade, ink jet, spin coating, brush coating, spray coating, roll coater, air knife coating, curtain coating, wire bar coating, gravure coating, and ink jet coating.

The photoelectric-conversion layer mentioned above basically includes a semiconductor and a perovskite structure. Here, the perovskite structure includes the perovskite film that is mentioned above. In embodiments of the present invention, it is preferable that the perovskite film that is thin includes a semiconductor layer formed on at least a part of a surface of the perovskite film. The semiconductor layer may be formed on an entire surface of the perovskite film.

The semiconductor is not particularly limited and may be a known one. As the semiconductor, examples include a simple substance such as silicon and germanium, a compound including elements selected from among elements of Group 3 to Group 5 and Group 13 to Group 15 of the periodic table, a metal oxide, a metal sulfide, metal selenium and a metal nitride. Examples of a preferred semiconductor include a gallium oxide, a titanium oxide, a tin oxide, a zinc oxide, an iron oxide, a tungsten oxide, a zirconium oxide, a hafnium oxide, a strontium oxide, indium, cerium, yttrium, lanthanum, vanadium, a niobium oxide, a tantalum oxide, cadmium sulfide, zinc sulfide, a lead sulfide, a silver sulfide, an antimony sulfide, a bismuth sulfide, a cadmium selenide, a lead selenide and a cadmium telluride. Examples of other chemical compound semiconductors include phosphides such as zinc, gallium, indium and cadmium, selenides of gallium-arsenic, selenides of copper-indium, sulfides of copper-indium, and nitrides of titanium. Specific examples of the semiconductor include Ga₂O₃, TiO₂, SnO₂, Fe₂O₃, WO₃, ZnO, Nb₂O₅, CdS, ZnS, PbS, Bi₂S₃, CdSe, CdTe, GaP, InP, GaAs, CuInS₂, CuInSe₂, and Ti₃N₄. The above-mentioned semiconductor may be used alone. Also, it is possible to use a combination of the above -mentioned semiconductors. In this case, when an additional component other than a metal oxide or a metal sulfide is added as a semiconductor, the mass ratio of the additional component to the metal oxide semiconductor or to the metal sulfide semiconductor is preferably 30% or less.

The shape of the semiconductor is not particularly limited, and examples of the shape of the semiconductor include a shape of filler, a particulate shape, a conical shape, a columnar shape, a tubular shape, and a flat plate shape. Also, it is possible to use a film in that semiconductors in the shape of fillers, particles, circular cones, pillars and/or tubes are aggregated, as a semiconductor layer. In this case, it is possible to use a semiconductor on that a perovskite film is previously arranged to coat a surface of the semiconductor, and also, it is possible to form a semiconductor layer first, and then, the semiconductor layer is arranged to cover a perovskite film. If the semiconductor has the shape of particles, which are preferably primary particles, and the average particle diameter is preferably in the range of 1 nm to 5000 nm, further preferably in the range of 2 nm to 100 nm. The term “average particle diameter” of the semiconductor means an average particle diameter of the primary particles, when 100 or more samples are observed with an electron microscope.

The method of forming the semiconductor is not particularly limited as long as the method does not interfere with an object of the present invention, and a known method may be used. Examples of the method for forming the semiconductor include a mist CVD method, a sputtering method, a CVD (Chemical Vapor Deposition) method, an SPD (Spray Pyrolysis Deposition) method, a vapor deposition method, and an ALD (Atomic Layer Deposition) method.

Also, the semiconductor may be provided with a surface treatment using an organic base. Examples of the organic base include diarylamine, triarylamine, pyridine, 4-t-butylpyridine, polyvinylpyridine, quinoline, piperidine, and amidine. Among all, pyridine, 4-t-butylpyridine, and polyvinylpyridine are preferable. The method of the surface treatment is not particularly limited and a known method may be used. In the case of the organic base is a liquid, the organic base is prepared as it is, for example. In the case of the organic base is a solid, an organic base solution in that the organic base is dissolved into an organic solvent is prepared, for example. The semiconductor is immersed in the liquid or the organic base solution at a temperature in the range of 0° C. to 80° C. for one minute to 24 hours to perform a surface treatment of the semiconductor.

The coating method of the perovskite film is as described above. In embodiments of the present invention, it is possible to use a base to form a perovskite film on the base including a semiconductor, an electron transport layer of a photoelectric-conversion layer and a first electrode arranged on the base.

The hole transport layer of the photoelectric-conversion element basically contains a polymer (preferably an electrically-conductive polymer). The hole transport layer of the photoelectric-conversion element normally has the function of supplying electrons to the perovskite film that is oxidized by photoexcitation, and transporting holes generated at an interface with the photoelectric-conversion layer to the second electrode. The hole transport layer of the photoelectric-conversion element is, for example, preferably arranged not only on the layer of the porous semiconductor layer but also in the pores of the porous semiconductor layer.

Examples of the constituent material of the hole transport layer of the photoelectric-conversion element include selenium, iodides such as copper iodide (CuI), cobalt complexes such as layered cobalt oxide, CuSCN, MoO₃, NiO, an organic hole transport material. Examples of the iodides include copper iodide (CuI). Examples of the layered cobalt oxide include AxCoO₂ (A=Li, Na, K, Ca, Sr, Ba; 0≤X≤1). Also, examples of the organic hole transport material include polythiophene derivatives such as poly-3-hexylthiophene (P3HT) and polyethylene dioxythiophene (PEDOT), fluorene derivatives such as 2,2′,7,7′-tetrakis-(N,N-di-p-methoxyphenylamine)-9,9′-spirobifluorene (spiro-MeO-TAD), carbazole derivatives such as polyvinylcarbazole, and also, triphenylamine derivatives, diphenylamine derivatives, polysilane derivatives, and polyaniline derivatives.

The method of forming the hole transport layer of the photoelectric-conversion element is not particularly limited as long as the method does not interfere with an object of the present invention, and a known method may be used. Examples of the method for forming the hole transport layer of the photoelectric-conversion element include a mist CVD method, a sputtering method, a CVD (Chemical Vapor Deposition) method, an SPD (Spray Pyrolysis Deposition) method, and a vapor deposition method, an ALD (Atomic Layer Deposition) method, a coating method such as dipping, dripping, doctor blade, ink jet, spin coating, brush coating, spray coating, roll coater, air knife coating, curtain coating, wire bar coating, gravure coating, and ink jet coating.

As long as the second electrode has an electrical conductivity and functions as an electrode, the second electrode is not particularly limited. For example, even an electrically-insulating material including an electrically-conductive layer, which is arranged at a side facing a hole transport layer of a photoelectric-conversion element and available as an electrode, may be used as the second electrode. In embodiments of the present invention, a second electrode preferably has a good contact property with a hole transport layer of a photoelectric-conversion element. It is also preferable that the difference of the work function of the second electrode and the work function of the electron transport layer is small, and the second electrode is chemically stable. Materials for the second electrode are not particularly limited but examples of the materials include a metal thin film of gold, silver, copper, aluminum, platinum, rhodium, magnesium, and indium, carbon, carbon black, electrically-conductive polymers, an organic electrical conductor such as an electrically-conductive metal oxide including an indium-tin composite oxide and a tin oxide doped with fluorine. Also, the average thickness of the second electrode is not particularly limited, the average thickness of the second electrode is preferably in a range of 10 nm to 1000 nm. Furthermore, a surface resistance of the second electrode has is not particularly limited, however, a lower value is preferable. For more details, the surface resistance of the second electrode is preferably 80 Ω/□ or less. Further preferably, the surface resistance of the second electrode is 20 Ω/□ or less. The lower limit of the surface resistance of the second electrode is not particularly limited, because the lower the surface resistance of the second electrode is, the better it is, however, the lower limit of the surface resistance of the second electrode would be 0.1 Ω/□ or more.

The method of forming the second electrode is not particularly limited as long as the method does not interfere with an object of the present invention, and a known method may be used. Examples of the method for forming the second electrode include a mist CVD method, a sputtering method, a CVD (Chemical Vapor Deposition) method, an SPD (Spray Pyrolysis Deposition) method, and a vapor deposition method.

The photoelectric-conversion element obtained as described above is useful as a power generation device and is applicable to devices of various purposes. Specifically, as a device favorably including a photoelectric-conversion element, an inverter device for converting a direct current output from the photoelectric-conversion element to an alternating current, an electric motor, a photoelectric-conversion device including lighting device(s) and a solar cell are named.

In the case of using a solution of precursor of a hole transport layer of an organic light-emitting element and/or a light-emitting layer as a raw-material solution, it is possible to obtain a film having a hole transport layer and/or light-emitting layer as major component with emission characteristics efficiently. Here, the term “major component” means the component of the film obtained by a method of forming a film according to an embodiment of the present invention having preferably 50% or more in terms of an atomic ratio to entire components of the hole transport layer and/or the light-emitting layer. Further preferably, the film has 70% or more of the major component to the entire components of the film, and most preferably 90% or more of the major component to the entire components of the film. Also, it is possible that the film has 100% of major component. In the case of manufacturing an organic light-emitting element using the method of forming a film according to an embodiment of the present invention, for example, at least a hole transport layer of an organic light-emitting element and/or a light-emitting layer are stacked on a substrate directly or via another layer by turning a raw material solution that contains an aprotic solvent by atomization into a mist or droplets, carrying the mist or droplets onto a substrate by a carrier gas, and causing a reaction of the mist or droplets adjacent to the substrate.

Hereinafter, in the case of manufacturing an organic light-emitting element using a method of forming a film according to an embodiment of the present invention, the embodiment will be described. According to the embodiment of manufacturing the organic light-emitting element, an anode is formed on a base, then, the hole transport layer of the organic light-emitting element is formed on the base, a light-emitting layer is formed on the base, and if desired, an electron transport layer (the electron transport layer of the organic light-emitting element) may be formed on the base and a cathode may be formed on the base, in this order, however, the order of forming anode, cathode and layers is not particularly limited thereto.

In the case of manufacturing an organic light emitting element using the method of forming a film according to an embodiment of the present invention, the base is preferably a transparent substrate.

### (Anode)

An anode may be a known one, and examples of the anode include the examples of the electrically-conductive film and the examples of the metal film mentioned above.

The method of forming the anode is not particularly limited as long as it does not interfere with an object of the present invention and may be a known method. Examples of forming the anode include a mist CVD method, a sputtering method, a CVD (Chemical Vapor Deposition) method, an SPD (Spray Pyrolysis Deposition) method, and a vapor deposition method.

The thickness of the anode is not particularly limited and suitably selected depending on a material of the anode, however, the thickness of the anode is usually in a range of 10 nm to 500 μm. The thickness of the anode is preferably in a range of 50 nm to 200

82 m.

(Hole Transport Layer of an Organic Light-Emitting Element)

The hole transport layer of an organic light-emitting element usually has functions that injecting holes as electric charges from an anode and transporting the holes. The hole transport layer of the organic light-emitting element is not particularly limited as long as the hole transport layer contains as a major component a film obtained by a method according to an embodiment of the present invention using a solution of a precursor of the hole transport layer of the organic light-emitting element. The thickness of the hole transport layer of the organic light-emitting element is not particularly limited, but from viewpoints of reducing drive voltage, and enhancement in external quantum efficiency and durability, the thickness of the hole transport layer of the organic light-emitting element is preferably 1 nm to 5 μm. The thickness of the hole transport layer of the organic light-emitting element is further preferably 5 nm to 1 μm, and most preferably 10 nm to 500 nm.

(Light-Emitting Layer)

The light-emitting layer usually has a function of emitting light by applying a voltage between the anode and the cathode. The light-emitting layer is not particularly limited as long as the light-emitting layer contains as a major component the film obtained by a method of forming a film according to an embodiment of the present invention using the precursor solution of the light-emitting layer. The thickness of the light-emitting layer is not particularly limited, but is preferably 1 nm to 100 μm. The thickness of the light-emitting layer is further preferably 5 nm to 50 μm, and most preferably 10 nm to 10 μm.

(Electron Transport Layer of Organic Light-Emitting Element)

The electron transport layer of the organic light-emitting element usually has one of functions that injecting electrons from a cathode, transporting electrons, and blocking holes injectable from an anode. The constituent material of the electron transport layer of the organic light-emitting element is not particularly limited and may be a known material. Examples of the electron transport layer of the organic light-emitting element include pyridine, pyrimidine, triazine, imidazole, triazole, oxazole, oxadiazole, fluorenone, anthraquinodimethane, anthrone, diphenylquinone, thiopyran dioxide, carbodiimide, fluorenylidenemethane, distyrylpyrazine, fluorine-substituted aromatic compound, heterocyclic tetracarboxylic anhydride such as naphthalene perylene, and also, phthalocyanine, derivatives thereof (may optionally form a fused ring with another ring), complexes of 8-quinolinol derivative(s) with metal(s), and metal phthalocyanine, and various complexes represented by complexes of benzoxazole and benzothiazole as a ligand with metal(s).

The thickness of the electron transport layer of the organic light-emitting element is not particularly limited, however, from viewpoints of reducing drive voltage, enhancement in external quantum efficiency and/or durability, the thickness of the electron transport layer is preferably 1 nm to 5 μm. The thickness of the electron transport layer of the organic light-emitting element is further preferably 5 nm to 1 μm, and most preferably 10 nm to 500 nm.

A method of forming the electron transport layer of the organic light-emitting element is not particularly limited as long as the method does not interfere with an object of the present invention, and a known method may be used. Examples of forming the electron transport layer of the organic light-emitting element include a mist CVD method, a sputtering method, a CVD (Chemical Vapor Deposition) method, an SPD (Spray Pyrolysis Deposition) method, a vapor deposition method, an ALD (Atomic Layer Deposition) method, a coating method such as dipping, dripping, doctor blade, ink jet, spin coating, brush coating, spray coating, roll coater, air knife coating, curtain coating, wire bar coating, gravure coating, and ink jet coating. According to embodiments of the present invention, the method of forming the electron transport layer of the organic light-emitting element is preferably a mist CVD method.

### (Cathode)

As long as the cathode has an electrical conductivity and functions as an electrode, the cathode is not particularly limited, and a known cathode may be used. For example, an electrically-insulating material including an electrically-conductive material layer, which is arranged at a side facing an electron transport layer of an organic light-emitting element and available as an electrode, may be used as a cathode. In embodiments of the present invention, a cathode preferably has a good contact property with an electron transport layer of an organic light-emitting element. It is also preferable that the difference of the work function of the cathode and the work function of the electron transport layer of the organic light-emitting element is small, and the cathode is chemically stable. Materials for the cathode are not particularly limited but examples of the materials include a metal thin film of gold, silver, copper, aluminum, platinum, rhodium, magnesium, and indium, carbon, carbon black, electrically-conductive polymers, an organic electrical conductor such as an electrically-conductive metal oxide including an indium-tin composite oxide and a tin oxide doped with fluorine. Also, the average thickness of the cathode is not particularly limited, the average thickness of the cathode is preferably in a range of 10 nm to 1000 nm. Furthermore, a surface resistance the cathode is not particularly limited, however, a lower value is preferable. For more details, the surface resistance of the cathode is preferably 80 Ω/□ or less. Further preferably, the surface resistance of the cathode is 20 Ω/□ or less. The lower limit of the surface resistance of the cathode is not particularly limited, however, because the lower limit of the surface resistance of the cathode becomes, the better the cathode is, the lower limit of the surface resistance of the cathode may be 0.1 Ω/□ or more.

For forming a cathode, the method is not particularly limited as long as the method does not interfere with an object of the present invention, and a known method may be used. Examples of forming the cathode include a mist CVD method, a sputtering method, a CVD (Chemical Vapor Deposition) method, an SPD (Spray Pyrolysis Deposition) method, and a vapor deposition method.

The organic light-emitting element obtained as described above is useful for a display device and a lighting device, for example, and also applicable to an electronic system including the display device and/or the lighting device, and a part of the system.

### Embodiments

Embodiments of the present invention are explained as follows, however, please note that the invention is not limited thereto.

### Embodiment 1

### 1. Film-Formation Apparatus

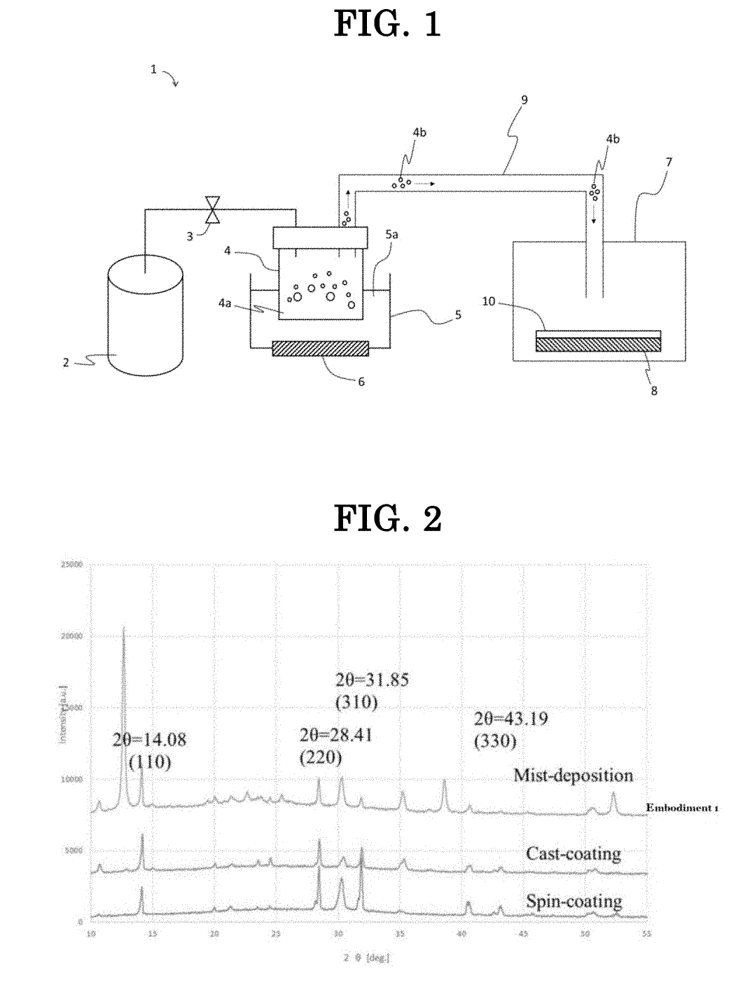

With reference to FIG. 1, a mist CVD apparatus 1 used in Embodiment 1 is explained as follows. The mist CVD apparatus 1 shown in FIG. 1 includes a carrier gas source 2 to supply a carrier gas to a mist, a flow control valve 3 for adjusting the flow rate of the carrier gas that is supplied from the carrier gas source 2, a mist source 4 containing a raw material solution 4a, a container 5 containing water 5a, an ultrasonic transducer 6 attached to a bottom of the container 5, a supply pipe 9 connecting the mist source 4 to the film-formation chamber 7, and a hot plate 8 arranged in the film-formation chamber 7. The substrate 10 is arranged on the hot plate 8.

### 2. Preparation of a Raw Material Solution

The raw material solution was prepared by mixing methylammonium lead iodide into γ-butyrolactone. The molar concentration of methylammonium lead ionide in the solution is 0.011 mol/L.

### 3. Preparation for Forming a Film

The raw material solution 4a obtained at “2. Preparation of raw material solution” was set in a mist source 4. Next, a glass/ITO substrate that is 15 mm square in size was arranged on a hot plate 8. The hot plate 8 was activated to raise the temperature in the film-formation chamber upto 120° C. Next, the flow control valve 3a and the flow control valve 3b were opened to supply carrier gas from carrier gas sources 2a and 2b into a film-formation chamber 7 for sufficiently replacing the atmosphere in the film-formation chamber 7 by nitrogen. After that, the flow rate of the carrier gas was set to be 4 L/minute.

### 4. Forming a Perovskite Film

Next, the ultrasonic transducer 6 was vibrated at 2.4 MHz, and vibrations were propagated through water 5a to the raw material solution 4a to atomize the raw material solution 4a to generate a mist 4b. The mist 4b was introduced into the film-formation chamber 7 through the supply tube 9 by the carrier gas. The mist thermally reacted in the film forming chamber 7 under atmospheric pressure at a temperature of 120° C. to form a film on the substrate 10. The film thickness was 1 μm, that took 20 minutes to be formed.

### 5. Evaluation

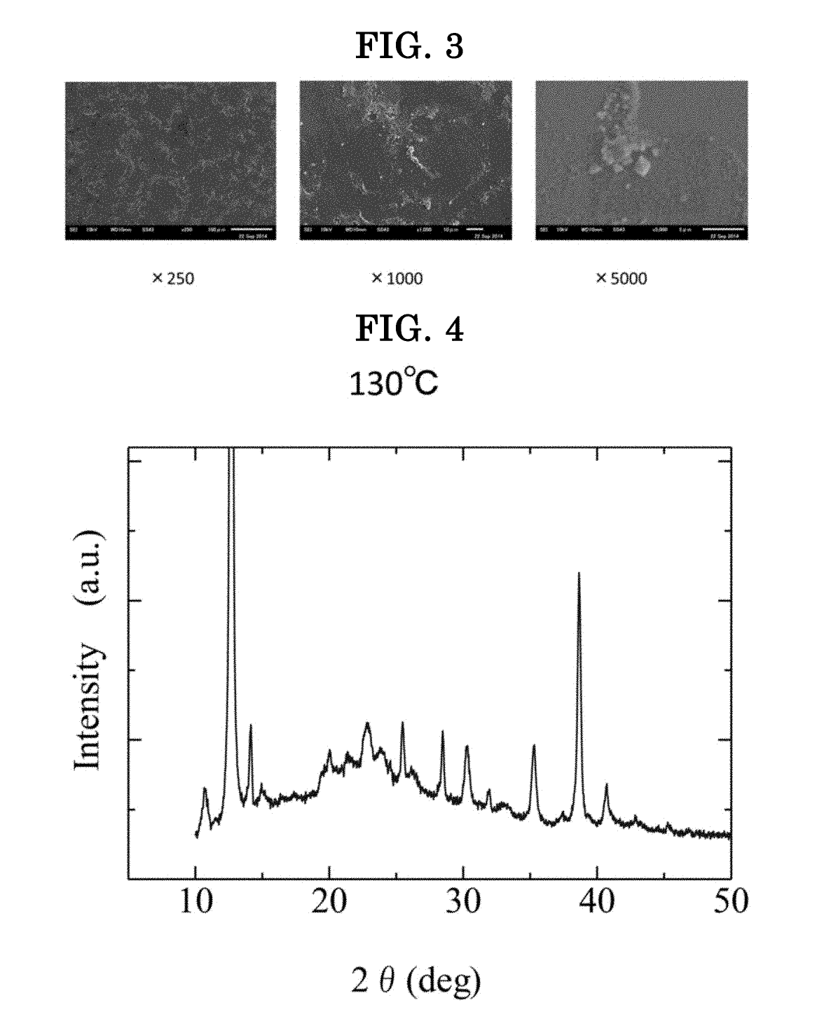

The perovskite film was identified using an XRD diffraction apparatus. The results are shown in FIG. 2. Also, a SEM observation was performed on the obtained film. The SEM image is shown in FIG. 3.

### Embodiment 2

Under the same conditions as conditions in Embodiment 1 except for that the film-forming temperature was 130° C., a perovskite film was obtained. In the same manner as in Embodiment 1, the crystal film that was obtained was identified as a perovskite film using an X-ray diffraction apparatus. The XRD chart is shown in FIG. 4.

### Embodiment 3

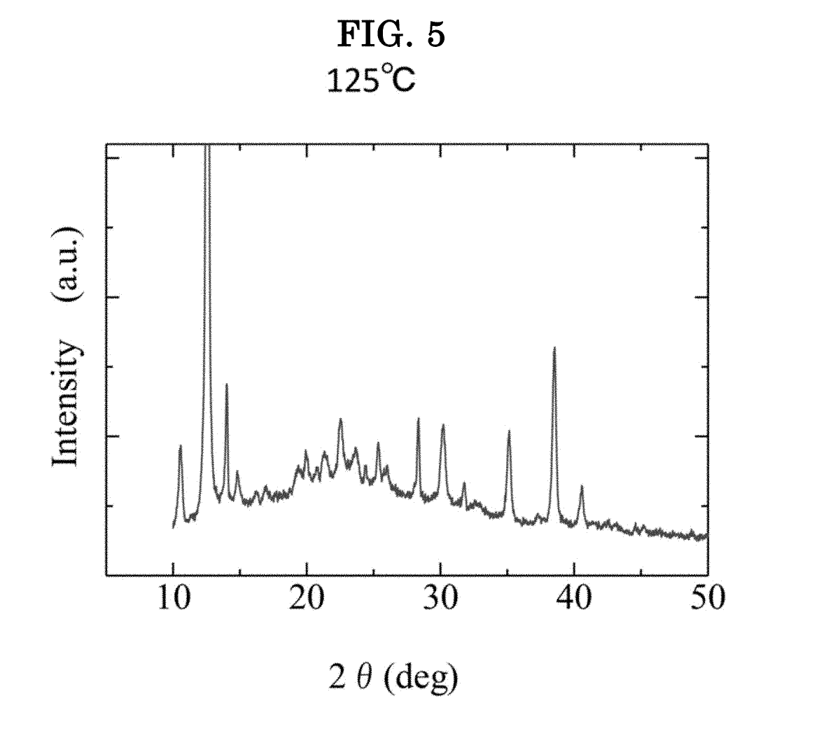

Under the same conditions as conditions in Embodiment 1 except for that the film-forming temperature was 125° C., a perovskite film was obtained. In the same manner as in Embodiment 1, the crystal film that was obtained was identified as a perovskite film using an X-ray diffraction apparatus. The XRD chart is shown in FIG. 5.

### Embodiment 4

Under the same conditions as conditions in Embodiment 1 except for that the film-forming temperature was 110° C., a perovskite film was obtained. In the same manner as in Embodiment 1, the crystal film that was obtained was identified as a perovskite film using an X-ray diffraction.

### Embodiment 5

Under the same conditions as conditions in Embodiment 1 except for that argon was used as a carrier gas instead of nitrogen, a perovskite film was obtained. In the same manner as in Embodiment 1, the crystal film that was obtained was identified to be a perovskite film using an X-ray diffraction apparatus.

### Embodiment 6

Under the same conditions as conditions in Embodiment 1 except for that y-butyrolactam was used instead of y-butyrolactone, a film was formed. In the same manner as in Embodiment 1, the obtained crystal film was identified using an X-ray diffraction apparatus, and as a result, the obtained film was a perovskite film.

### COMPARATIVE EXAMPLE 1

Under the same conditions as conditions in Embodiment 1 except for that water was used instead of y-butyrolactone. However, there was no film formed on the substrate.

### COMPARATIVE EXAMPLE 2

Under the same conditions as conditions in Embodiment 1 except for that a mixed solvent of methanol and water (methanol:water=95:5) was used instead of γ-butyrolactone. However, there was no film formed on the substrate

The film obtained in each of Embodiments has a perovskite structure sufficient in quality, because the films in Embodiments were formed at lower temperatures and the damage to the films due to heat was minimized. In each of Comparative Examples, however, there was no film formed and failed.

### Embodiment 7

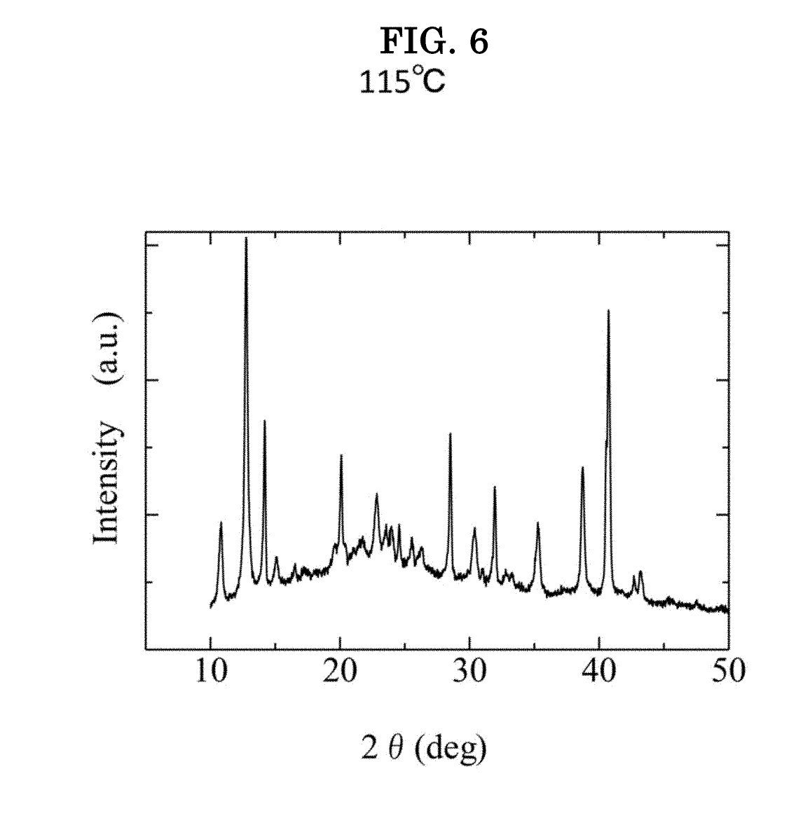

Under the same conditions as conditions in Embodiment 1 except for that the film-forming temperature was set at 115° C., a perovskite film was obtained. Also, in the same manner as Embodiment 1, the obtained crystal film was identified as a perovskite film using an X-ray diffraction (XRD) apparatus. The XRD chart is shown in FIG. 6.

### Embodiment 8

### 1. Film-Formation Apparatus

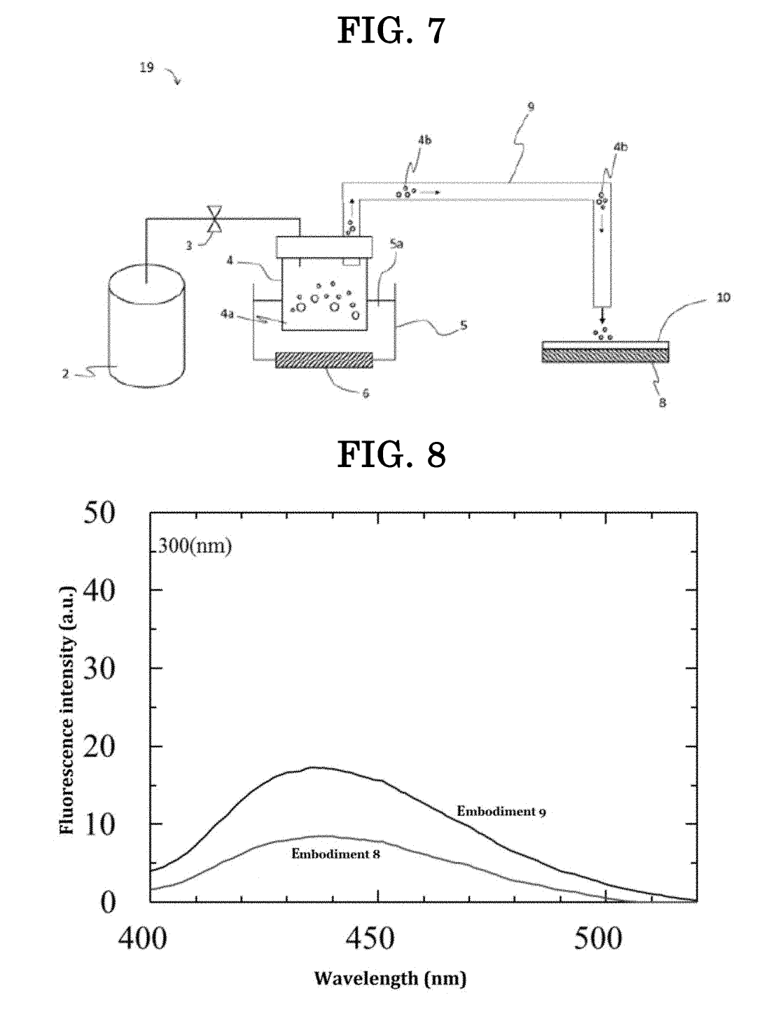

With reference to FIG. 7, a film-formation apparatus 19 used in Embodiment 8 is explained as follows. The film-formation apparatus 19 shown in FIG. 7 includes a carrier gas source 2 to supply a carrier gas to a mist, a flow control valve 3 for adjusting the flow rate of a carrier gas that is supplied from the carrier gas source 2, a mist source 4 containing a raw material solution 4a, a container 5 containing water 5a, an ultrasonic transducer 6 attached to a bottom of the container 5, a hot plate 8, and a substrate 10 arranged on the hot plate 8, and a supply pipe 9 connecting the mist source 4 to a position adjacent to the substrate 10.

### 2. Preparation of a Raw Material Solution

The raw material solution was prepared by mixing α-NPD into γ-butyrolactone. The molar concentration of α-NPD in the solution is 0.0020 mol/L.

### 3 . Preparation for Forming a Film

The raw material solution 4a obtained at “2. Preparation of raw material solution” was set in a mist generation source 4. Next, a glass/ITO substrate that is 15 mm square in size was arranged on a hot plate 8. The hot plate 8 was activated to raise the temperature of the substrate 10 up to 180° C. Next, the flow control valve 3 was opened to supply carrier gas from a carrier gas source 2 and a flow rate of the carrier gas was set at 4 L/minute. As a carrier gas, nitrogen was used.

### 4. Forming a Hole Transport Layer of an Orgainc Light-Emitting Element

Next, the ultrasonic transducer 6 was vibrated at 2.4 MHz, and vibrations were propagated through water 5a to the raw material solution 4a to atomize the raw material solution 4a to generate a mist 4b. The mist 4b was carried through a supply tube 9 by a carrier gas onto a substrate 10. The mist adjacent to the substrate 10 thermally reacted and a hole transport layer of the organic light-emitting element was formed on the substrate 10. The obtained hole transport layer has 50 nm in thickness, that took 10 minutes to be formed. A fluorescence spectrum of the obtained hole transport layer with the substrate was measured at an excitation wavelength that is 300 nm, and the measurement result is shown in FIG. 8. FIG. 8 indicates that the obtained hole transport layer with the substrate has a light-emitting peak that is in a range of 430 nm to 450 nm in wavelength.

### Embodiment 9

Under the same conditions as conditions in Embodiment 8 except for that the film-forming temperature was set at 140° C., a hole transport layer was obtained. Also, in the same manner as Embodiment 8, a fluorescence spectrum of the obtained hole transport layer with the substrate was measured, and the measurement result is shown in FIG. 8. FIG. 8 indicates that the obtained hole transport layer with the substrate has a light-emitting peak that is in a range of 430 nm to 450 nm in wavelength. Also, the obtained hole transport layer with the substrate has better light-emitting characteristics with a higher fluorescence intensity than the hole transport layer obtained in Embodiment 8.

### Embodiment 10

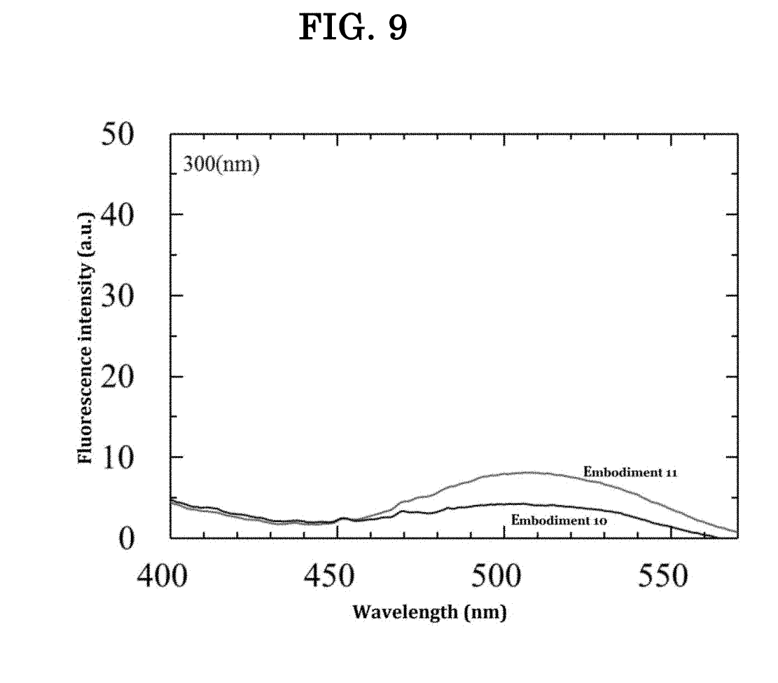

Under the same conditions as conditions in Embodiment 8 except for that Alq3 was used instead of α-NPD, the concentration of Alq3 in the solution was 0.0025 mol/L to prepare a mixed solution, which was used as a raw material solution, and the laminate obtained in Embodiment 8 was used as a substrate, a light-emitting layer was formed on the hole transport layer formed in Embodiment 8 of the organic light-emitting element. The obtained light-emitting layer has 50 nm in thickness, that took 10 minutes to be formed. In the same manner as Embodiment 8, a fluorescence spectrum of the obtained light-emitting layer with the substrate was measured at an excitation wavelength that is 300 nm, and the measurement result is shown in FIG. 9. FIG. 9 indicates that the obtained light-emitting layer with the substrate has a light-emitting peak that is in a range of 500 nm to 520 nm in wavelength.

### Embodiment 11

Under the same conditions as conditions in Embodiment 10 except for using a laminate obtained in Embodiment 9 as a substrate, a light-emitting layer with a substrate was obtained. Also, in the same manner as in Embodiment 8, a fluorescence spectrum of the obtained light-emitting layer with the substrate was measured, and the measurement result is shown in FIG. 9. FIG. 9 indicates that the obtained light-emitting layer with the substrate has a light-emitting peak that is 500 nm to 520 nm in wavelength. Also, the obtained light-emitting layer with the substrate in this Embodiment had a higher emission intensity and a better emittance property of light than the light-emitting layer with the substrate obtained in Embodiment 10.

### (Manufacturing Embodiment of an Organic Light-Emitting Element)

An organic light-emitting element was manufactured. The organic light-emitting element includes a laminate obtained in Embodiment 10, and a cathode of aluminum formed on the laminate by use of a vacuum vapor deposition method.

### INDUSTRIAL APPLICABILITY

Since it is possible to form films of various materials, a method according to an embodiment of the present invention is applicable to various industries. For example, it is possible to form a perovskite film suitably, and that is useful for the fields of photoelectric-conversion elements, solar cells and optical sensors.

### REFERENCE SIGNS LIST

1 a mist CVD (Chemical Vapor Deposition) apparatus

2 a carrier gas source

3 a flow-control valve

4 a mist source

4a a raw material solution

4b a mist

5 a container

5a water

6 an ultrasonic transducer

7 a film-formation chamber

8 a hot plate

9 a supply pipe

10 a substrate

19 a film-formation apparatus

1. A method of forming a film comprising:
turning a raw material solution that comprises an aprotic solvent by atomization into a mist or droplets;
carrying the mist or droplets by a carrier gas onto a base; and
forming a film on the base by a reaction of the mist or droplets.

2. The method of forming the film of claim 1, wherein the aprotic solvent is represented by Chemical Formula (1), 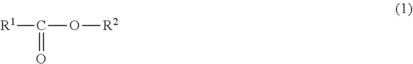
in the Chemical Formula (1), wherein
R¹ and R² are the same or different and each represents a hydrogen atom, a halogen atom, an optionally substituted hydrocarbon group or an optionally substituted heterocyclic group, and
R¹ and R² may be taken together to form a ring.

3. The method of claim 1, wherein the aprotic solvent is represented by Chemical Formula (2), 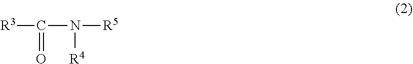
in the Chemical Formula (2), wherein
R³, R⁴, and R⁵ are the same or different and each represents a hydrogen atom, a halogen atom, an optionally substituted hydrocarbon group, or an optionally substituted heterocyclic group, and two arbitrary groups selected from among R³, R⁴, and R⁵ may bond each other to form a ring.

4. The method according to claim 1, wherein the raw material solution comprises an organometal halide compound.

5. The method according to claim 1, wherein the the raw material solution comprises an ammonium compound.

6. The method according to claim 1, wherein the reaction of the mist or droplets is a thermal reaction of the mist or droplets conducted at 250° C. or less.

7. The method according to claim 1, wherein the base is a glass substrate

8. The method according to claim 1, wherein the base comprises a tin-doped indium oxide layer or a fluorine-doped indium oxide layer.

9. The method according to claim 1, wherein the base comprises a titania layer.

10. A film obtained by the method according to claim 1.

11. The film according to claim 10 comprising:
a Perovskite structure.

12. A photoelectric-conversion element comprising:
the film according to claim 11.

13. The method according to claim 1, wherein the raw material solution comprises an amine derivative.

14. The method according to claim 1, wherein the raw material solution comprises a metal complex.

15. A method of manufacturing an organic light-emitting element comprising:
forming a hole transport layer and/or a light-emitting layer that is directly or via another layer on a base by forming a mist or droplets by atomization of a raw-material solution comprising an aprotic solvent, carrying the mist or droplets by a carrier gas onto a base, and forming the hole transport layer and/or the light-emitting layer on the base by causing a reaction of the mist or droplets on the base.

16. The method of claim 15, wherein the raw-material solution comprises an amine derivative.

17. The method of claim 15, wherein the raw-material solution comprises a metal complex.

18. An organic light-emitting element obtained by the method according to claim 15.

19. The method according to claim 2, wherein the raw material solution comprises an organometal halide compound.

20. The method according to claim 3, wherein the raw material solution comprises an organometal halide compound.
